(19) United States
(12) Patent Application Publication
(10) Pub. No.: US 2020/0011921 A1
(43) Pub. Date: Jan. 9, 2020

(54) METHOD FOR ACCURATELY LOCATING A CABLE DEFECT OF A CABLE LAID IN THE GROUND

(71) Applicant: BAUR GmbH, Sulz (AT)

(72) Inventors: Martin Jenny, Dornbirn (AT); Martin Baur, Sulz (AT); Peter Herpertz, Muntlix (AT)

(73) Assignee: BAUR GmbH, Sulz (AT)

(21) Appl. No.: 16/488,651

(22) PCT Filed: Mar. 15, 2018
(86) PCT No.: PCT/AT2018/000014

§ 371 Date: Aug. 26, 2019

(30) Foreign Application Priority Data
Mar. 29, 2017 (AT) A 129/2017

(51) Int. Cl. G01R 31/08

(52) U.S. Cl. CPC G01R 31/083

(57) ABSTRACT

A method for accurately locating a cable defect of an in-ground cable for transmitting electricity, in which a precise position is established with a mobile pinpointing device based on an approximate position of the cable defect that was established previously. A distance of the defect location of the cable from a current position of the mobile pinpointing device is determined by the mobile pinpointing device. The current position is captured by the mobile pinpointing device using a GPS receiver. Subsequently, at least one possible precise position is determined by the pinpointing device based on the captured current position of the pinpointing device, the established distance of the defect location from the current position of the pinpointing device and the extent of the cable that is stored in the pinpointing device. At least one target location for the precise position of the cable defect is displayed on a display of the pinpointing device in a map, stored therein, of the surroundings of the cable defect or in an image recorded by a camera of the pinpointing device.

### TECHNICAL FIELD

The invention relates to a method for pinpointing a cable fault of an underground cable for transmitting electrical power, in which a mobile pinpointing device is used to establish a precise position of the cable fault on the basis of an approximate position of the cable fault that was established previously by way of pre-location, wherein a distance of the fault location of the cable from a present position of the mobile pinpointing device is determined by the mobile pinpointing device.

### BACKGROUND

In underground cables for transmitting electrical power, faults can occur that require repairs of the cable in the region of the fault location. These may be low-voltage, medium-voltage or high-voltage cables. In order to be able to do the repairs, it is initially required to locate the cable fault. Methods in this respect are known.

In known methods for locating cable faults, initially pre-location (rough location) is performed. One example of this is the secondary/multiple impulse method, which is a high-voltage measurement method suitable for high-resistive cable faults. To locate a cable fault, a first reflection of a voltage impulse at the cable end and a second reflection due to a flashover at the fault location are captured. In addition, further methods for pre-location are known, for example decay and ICM.

The result of such pre-location gives the cable length between the location where the pre-location signal was injected and the fault location. If the cable route (=path of the cable underground) is known, it can be used to determine the position of the cable fault. For the cable route, either geo data are available, or the routing section of the underground cable needs to be determined. Such determinations of the routing section (=of the cable path) are performed for example by injecting a tone frequency into the underground cable isolated from the grid and a search coil guided along the cable route aboveground.

However, the known methods for pre-location give only an approximate position of the fault location of the cable. One reason therefor is in particular that, when laying a cable along the cable route, deviations of a greater or lesser extent from the shortest route occur. For example, the laying depth can vary, cable loops may be present, etc. Overall, an inaccuracy of the pre-location of the cable fault is obtained that is typically in the range from 1% to 10% of the length of the cable between the location of the measurement signal injection and the cable fault. Depending on the length of said section, the deviation between the actual position of the cable fault and the approximate position of the cable fault established by pre-location can thus lie in the region of a few meters to few tens of meters.

It is also already known to show the established approximate position of the cable fault on a map. Pre-location is performed using a pre-location device that is typically located in a measurement trolley in the region of a cable station from which a number of cables leave. The paths thereof are known as “GIS data” and can be stored in the pre-location device. Once the user has input the start of the cable on which pre-location is performed and the distance of the cable fault has been established, an approximate position of the cable fault in a map presented on the display unit of the pre-location device can be shown. The pre-location device can also have a GPS receiver so that the position of the measurement trolley can also be shown in the map. Subsequently, the person performing the fault location can use satellite navigation to move to the approximate position of the cable fault.

In order to then establish a precise position of the cable fault on the basis of the previously performed pre-location (rough location), so that the excavation work can be performed at this position at a later time, an acoustic pinpointing method is known. Here, a surge voltage generator is used to inject surge voltage impulses into the cable. These high-energy impulses produce a voltage impulse that propagates in the cable and results in a flashover at the fault location. Here, an acoustic signal that is detectable using a ground microphone in the area surrounding the cable fault is produced. It is then possible using the ground microphone to search for the location of the greatest amplitude of the breakdown sound to establish the position of the cable fault. For each measurement, the ground microphone is placed onto the ground and waits for the next surge voltage impulse and the acoustic signal thus triggered. However, searching for a fault in this manner is highly time-consuming.

An improvement of this method is the determination of a distance of the fault location of the cable from the present position of a mobile pinpointing device. To this end, the mobile pinpointing device has, in addition to the ground microphone that is used to detect the acoustic signal, an electromagnetic sensor with which the surge voltage impulse transmitted via the cable and the associated electromagnetic field are detected. A time difference between said detected electromagnetic signal and the detected acoustic signal is captured. This time difference corresponds to the time required by the sound traveling from the fault location to the mobile pinpointing device (wherein the time taken for the surge voltage impulse to propagate is negligible, by contrast). It is thus possible to determine from this established time difference a distance from the fault location to the present position of the mobile pinpointing device. This distance is shown on a display of the mobile pinpointing device. The person locating the cable fault can thus ascertain with its repeating measurements whether the distance from the fault location decreases. When said distance has a minimum, the person is situated directly above the fault location of the cable. In this way, searching for the precise position of the cable fault is significantly simplified.

An acoustic pinpointing method in which the time difference between the acoustic signal and the surge voltage impulse is evaluated to establish the distance from the cable fault is disclosed for example by EP 2 405 279 A2. That document deals with a method in which acoustic pinpointing can be performed even in very loud ambient conditions.

In addition to devices for pinpointing that are used after a cable fault has occurred, “online monitoring” for permanently monitoring cables during operation is also known. Fixedly mounted, stationary monitoring devices are employed herefor.

CN 105676074 A discloses a device for online monitoring of high-voltage lines in the form of overhead lines. Measurement units are installed on high-voltage pylons at a spacing of 5 km to 50 km that detect traveling waves occurring in the case of a flashover. Time synchronization is performed by way of GPS, and the time difference between the arrivals of the traveling waves is evaluated at a base station to approximately establish the position of the fault location.

### SUMMARY

It is the object of the invention in a method for pinpointing of the type stated in the introductory part to further simplify finding the precise position of the cable fault. This is accomplished by way of a method having one or more features of the invention.

In the method of the invention, a GPS receiver of the pinpointing device is used to capture the present position of the pinpointing device. At least one possible precise position of the cable fault is determined based on said captured present position of the pinpointing device, on the established distance of the fault location of the cable from the present position of the pinpointing device, and on the path of the cable stored in the pinpointing device. At least one target location for the precise position of the cable fault is shown on a display of the pinpointing device in a map of the area surrounding the approximate position of the cable fault that is stored in the pinpointing device or in an image recorded by a camera of the pinpointing device.

At least two measurements at different present positions of the pinpointing device are preferably carried out. This makes it possible to obtain a unique result for the precise position of the cable fault, which is then shown as the target location in the stored map or in the image recorded by the camera on the display of the pinpointing device.

Using the method according to the invention, at least one target location, preferably exactly one target location, for the precise position of the cable fault is thus shown directly to the user in the map or in the image, which means that said person can immediately move to said target location. Finding the precise position of the cable fault to perform there excavation work for exposing and repairing the cable can thus be simplified and accelerated.

### BRIEF DESCRIPTION OF THE DRAWINGS

Further advantages and details of the invention will be explained below on the basis of the attached drawing, in which:

FIG. 1 shows a schematic depiction of the pinpointing operation;

FIG. 2 shows a schematic diagram of the pinpointing device;

FIG. 3 shows a depiction for illustrating the establishing of possible precise positions of the cable fault;

FIG. 4 shows a depiction in accordance with FIG. 3 after a second measurement was performed;

FIG. 5 shows a depiction of the display of the pinpointing device;

FIG. 6 shows a schematic diagram in accordance with FIG. 2 for a modified embodiment of the invention; and

FIG. 7 shows a depiction of the display of the pinpointing device in accordance with said modified embodiment of the invention.

### DETAILED DESCRIPTION

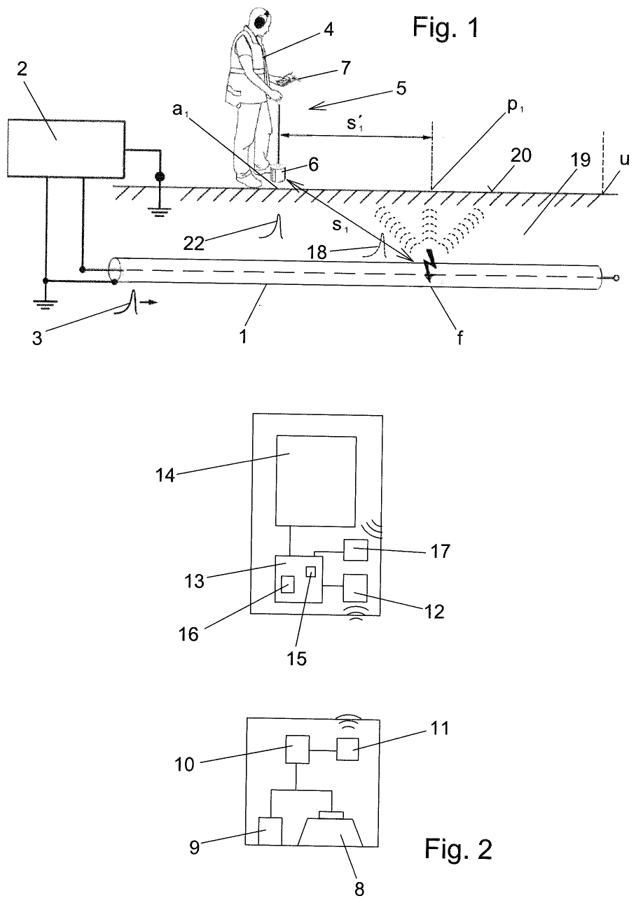

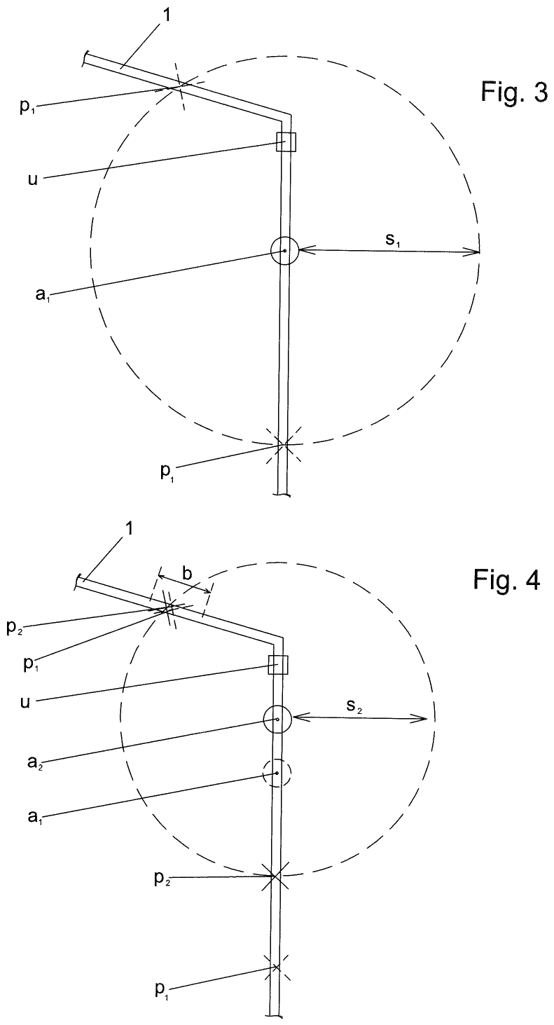

A method for pinpointing according to the invention will be described below on the basis of the figures. FIG. 1 shows a schematic depiction of an underground cable 1 for transmitting electrical power. This may be a low-voltage cable (up to 1 kV), a medium-voltage cable (1 kV to 60 kV) or a high-voltage cable (>60 kV, for example 110 kV, 220 kV or 380 kV). The cable has, at a fault location f, a cable fault, in particular a high-resistive cable fault or an intermittent cable fault. By way of pre-location (rough location), which is known, an approximate position u of the cable fault was established.

For pinpointing (=post-location) of the cable fault, surge voltage impulses 3 are injected into the cable 1 using a surge voltage generator 2 that is connected to the cable. For example, a surge voltage impulse can be injected every three seconds. The intervals between the individual surge voltage impulses can also have values that differ therefrom, but are preferably in the range between 1 s and 10 s.

The height of the surge voltage impulses can also depend on the type of the cable that is to be tested. In general, the height of the surge voltage impulses will be greater than 1 kV, for example in the case of low-voltage cables in the range from 2 to 5 kV. In the case of medium-voltage and high-voltage cables, the height of the voltage impulses will generally be more than 5 kV, for example in the range from 10 to 40 kV. Expediently, the height of the voltage impulses can be set at the surge voltage generator. Advantageously, at least one settable range from 2 kV to 30 kV will be covered by the surge voltage generator, wherein the covered range can also be greater.

A person 4 locating the cable fault carries a mobile pinpointing device 5. The latter comprises two separate devices in the exemplary embodiment shown, specifically a capturing unit 6 and a display unit 7. The data transfer between the capturing unit 6 and the display unit 7 is wireless in the exemplary embodiment, for example using Bluetooth, but it could also be done by wire.

The capturing unit 6 has a ground microphone 8 and an electromagnetic sensor 9. Signals emitted by the ground microphone 8 and by the electromagnetic sensor 9 are captured by an analog circuit, are A/D-converted and fed to a microprocessor unit. The analog circuit, the A/D converter and the microprocessor unit are depicted schematically in FIG. 2 as an electronic signal processing unit 10. Furthermore, the data is transmitted by a transmitter 11 to a receiver 12 of the display unit 7. The received data is evaluated in a microprocessor unit 13, and a display 14 is actuated by the microprocessor unit 13. A microprocessor 15 and a memory 16 are schematically indicated in the microprocessor unit 13. The microprocessor unit 13 will generally have further components, which are not depicted in FIG. 2.

Furthermore, the display unit 7 has a GPS receiver 17, connected to the microprocessor unit 13, for receiving GPS signals.

When data is also to be transmitted from the display unit 7 to the capturing unit 6, which will generally be expedient, the transmitter 11 and the receiver 12 will be configured as a respective transceiver unit. In the case of data transfer by wire, the transmitter 11 and the receiver 12 could also be dispensed with. In that case, only one microprocessor unit might be provided either in the display unit 7 or in the capturing unit 6, said microprocessor unit having at least one microprocessor 15 and a memory 16.

The display unit can be a smartphone or a tablet. A commercially available smartphone or tablet with the corresponding setup can be used. However, the display unit can also be configured specifically for this application.

In a modified embodiment, the capturing unit 6 and the display unit 7 could also be connected to a common device.

Signals received by the ground microphone can be output to headphones and/or loudspeakers, providing acoustic feedback to the user.

To pinpoint the cable fault, repeating surge voltage impulses 3 are injected into the cable 1 using the surge voltage generator 2. The surge voltage impulses 3 in each case bring about a flashover at the fault location f of the cable 1, as a result of which an acoustic signal in the form of an acoustic impulse 18 is produced. This acoustic impulse 18 propagates in all directions in the earth 19 surrounding the cable 1.

When a surge voltage impulse 3, which has been injected into the cable 1, passes through the region below the mobile pinpointing device 5, the electromagnetic signal that is brought about thereby is detected by the electromagnetic sensor 9 as an electromagnetic impulse. This detected electromagnetic impulse is used by the microprocessor unit 13 as a first trigger, triggering a time measurement. When the acoustic impulse 18 that was produced by the flashover triggered by the surge voltage impulse is received by the ground microphone 8 and a corresponding signal is output to the microprocessor unit 13, this is used by the microprocessor unit 13 as a second trigger signal that ends the time measurement. The distance s₁ of the underground actual fault location f of the cable 1 from the present position a₁ of the pinpointing device 5 is determined from the elapsed time At between the first and the second trigger signal. The time of flight of the surge voltage impulse between the region of the present position of the mobile pinpointing device 5 and the fault location f or the propagation time of the electromagnetic impulse that was caused by the surge voltage impulse and detected by the electromagnetic sensor 9 can here be neglected, because the propagation velocity v_{A} of the acoustic impulse, that is to say the sound velocity in the earth 19, is significantly lower. The distance s₁ is thus determined as per:

s₁=v_{A}·Δt

This determination of the distance s₁ of the actual fault location f of the cable 1 from the present position a₁ of the mobile pinpointing device 5 is known and is also referred to as “coincidence method.”

The present position a₁ of the mobile pinpointing device 5 is captured using the GPS receiver 17 of the mobile pinpointing device 5. In addition, the geographic path of the cable 1, that is to say the routing section thereof, is stored in the memory 16 of the mobile pinpointing device 5. In this respect, available geo data for the cable path can have been previously stored in the memory 16, for example by transmission from a GIS database. Also, the cable path can have been input by the user. Should the exact path of the cable not be known, the latter would have to be established first. Methods for determining the cable path are known, as already mentioned.

Possible precise positions p₁ of the cable fault are established by the pinpointing device 5 on the basis of the established distance s₁ of the actual fault location f from the present position a₁ of the pinpointing device in connection with the current position a₁ of the pinpointing device, established by way of the GPS receiver, and the path of the cable 1 that is stored in the pinpointing device 5. Said possible positions are obtained as points of intersection of a circle, having the radius s₁ and the present position al of the pinpointing device 5 as the center, with the stored path of the cable 1.

The actual precise position p₁ of the cable fault is the location on the ground 20 vertically above the actual fault location f. When determining the possible precise positions p₁ of the cable fault, it is thus optionally possible for the routing depth of the cable 1, which is known or for which a typical standard value can be used, to be taken into consideration. Rather than s₁, the value s₁′ (=distance of the present position a₁ of the pinpointing device 5 from the precise position p₁ of the cable fault on the ground 20 lying vertically above the actual fault location f) can be used for the radius of the circle. The difference between s₁ and s₁′ can, however, approximately also be neglected.

In the exemplary embodiment, two points of intersection of the circle with the path of the cable are obtained, that is to say two possible precise positions p₁ of the cable fault. It could be also possible for more than two points of intersection and thus more than two possible precise positions p₁ of the cable fault to be obtained, in particular when the cable 1 is branched or has an S shape or a U shape.

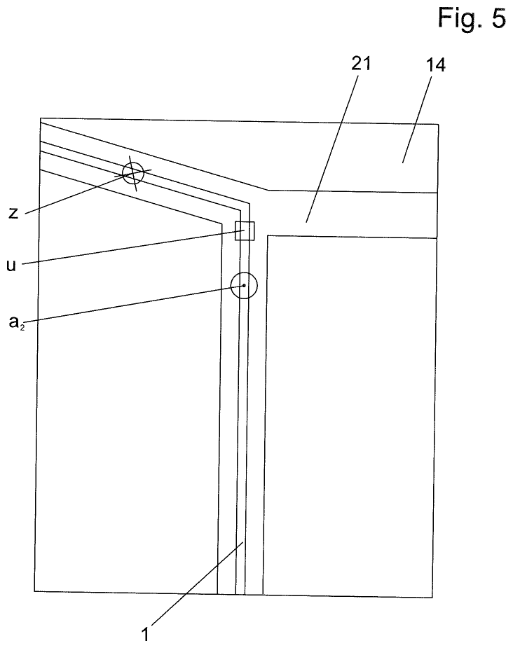

A unique precise position of the cable fault can be determined, that is to say a single possible precise position of the cable fault, by way of at least one further measurement with a changed present position a₂ of the mobile pinpointing device 5. If, after the first measurement, the position of the mobile pinpointing device 5 is changed, the established distance between the now present position a₂ of the mobile pinpointing device 5 and the fault location f also changes. This changed distance is denoted in FIG. 4 as s₂ (again, it could be possible to use a corrected distance s₂′ taking into account the routing depth of the cable 1). The circle with the now present position a₂ of the mobile pinpointing device 5 as the center and s₂ (or s₂) as a radius again forms, in the exemplary embodiment, two points of intersection with the path of the cable 1, which represent possible precise positions p₂ of the cable fault. The possible precise positions p₁ of the cable fault obtained from the first measurement are illustrated in FIG. 4 by dashed crosses. In the region of the actual fault location f, the possible precise positions p₁, p₂ of the cable fault, obtained from the different measurements, largely coincide, except for measurement errors (for example on account of the routing depth of the cable 1 not being taken into consideration or being taken into consideration with insufficient precision). That is to say, where possible precise positions p₁, p₂ of the cable fault, which were obtained in two or more measurements, are located within a tolerance range b, a target location for the cable fault is fixed, and the other possible precise positions p₁, p₂, which have a greater distance than b from one another, are discarded. This target location z is shown on the display 14 of the mobile pinpointing device 5, specifically on a map that was previously stored on the pinpointing device 5. The map that was previously stored on the pinpointing device thus in any case comprises an area surrounding the approximate position u of the cable fault established in the pre-location method (wherein the map preferably contains at least a region of 500 m around the approximate position u of the cable fault that was established in the pre-location). The map can be stored in the pinpointing device 5 from the beginning or have been downloaded from the Internet for the respective application. As is apparent from FIG. 5, the map illustrates street paths 21. Also shown is the path of the cable 1. In addition, the present position a₁ of the mobile pinpointing device 5 is shown. Preferably, the approximate position u of the cable fault, established in the pre-location, is also shown.

The target location z shown in the map can be the possible precise position p₂ of the cable fault that was established in the last performed measurement and lies within the tolerance range b. The possible precise positions p₁, p₂ of the cable fault that were obtained from a plurality of preceding measurements and lie within the tolerance range b can also be shown as target locations z (which minimally deviate from one another due to measurement errors). Instead, an average value of possible precise positions p₁, p₂ of the cable fault that lie within the tolerance range b and were established in two or more preceding measurements could be shown, for example, as the target location z.

The tolerance range b can be a specified maximum distance between the precise positions p₁, p₂ of the cable fault that were obtained in the individual measurements. The tolerance range b can also depend on the established distance s between the present position a₁ of the pinpointing device 5 and the actual fault location f of the cable 1, wherein the tolerance range b is expediently selected to be smaller in the case of a smaller distance s than in the case of a greater distance s.

After the target location z is shown in the map on the display 7, the person 4 performing the pinpointing can proceed directly to the target location z. Here, the localization of the actual fault location can still be verified by measurements of the volume level.

With the method according to the invention, the user can thus perform pinpointing in a highly time-saving and reliable manner.

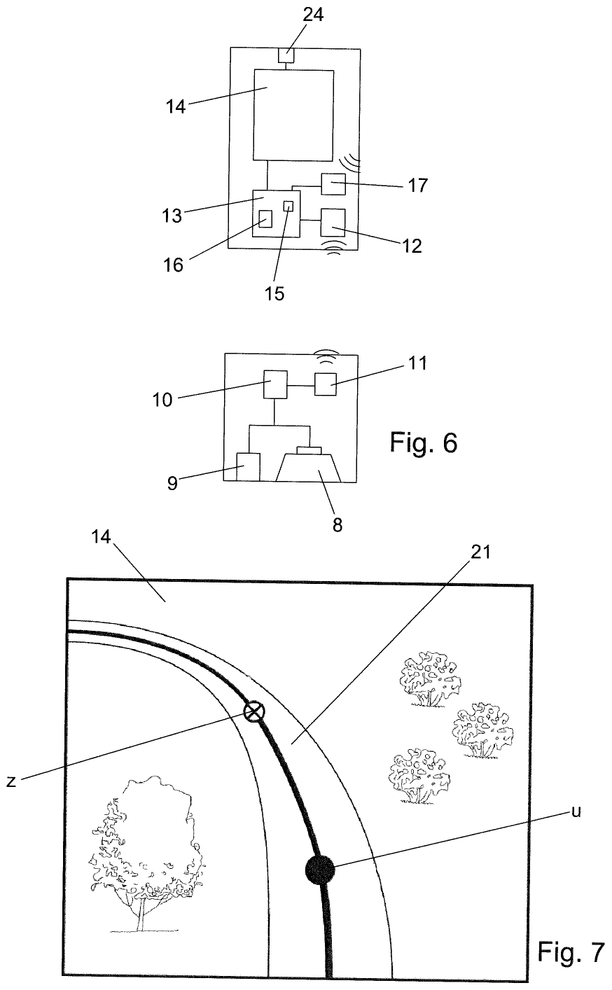

A modified embodiment of the invention will be explained below with reference to FIGS. 6 and 7. Aside from the differences described below, the modified embodiment corresponds to the previously described embodiment, and the description thereof is correspondingly applicable, in conjunction with the described possible modifications.

The difference with respect to the previously described embodiment is that the user records an image (photo) of the environment of the approximate position u of the cable fault using a camera 23 of the mobile pinpointing device 5 for showing the at least one target location z on the display 14 of the mobile pinpointing device 5, and the at least one target location z is shown in said image, cf. FIG. 7. The at least one, preferably exactly one, target location z for the actual fault location is thus superposed onto the real image recorded by the camera of the pinpointing device. Should the target location z (or at least one of the target locations z) be located outside the image recorded by the camera, the user will be notified accordingly.

This modified embodiment of the invention can also be combined with the previously described embodiment of the invention, with it being the user's choice whether the map or an image recorded by the camera is shown in the display.

Various further modifications of the invention are conceivable and possible. For example, the evaluations by the microprocessor unit 13 described previously could likewise be performed entirely or partially in the microprocessor unit of the capturing unit 6.

### LEGEND FOR THE REFERENCE SIGNS:

1 Cable

2 Surge voltage generator

3 Surge voltage impulse

4 Person

5 Mobile pinpointing device

6 Capturing unit

7 Display unit

8 Ground microphone

9 Electromagnetic sensor

10 Electronic signal processing unit

11 Transmitter

12 Receiver

13 Microprocessor unit

14 Display

15 Microprocessor

16 Memory

17 GPS receiver

18 Acoustic impulse

19 Earth

20 Ground

21 Street path

22 Electromagnetic impulse

23 Camera

f Fault location of the cable

u Approximate position of the cable fault

a₁, a₂ Present position of the pinpointing device

p₁, p₂ Possible precise position of the cable fault

b Tolerance range

z Target location

1. A method for pinpointing a cable fault of an underground cable for transmitting electrical power, the method comprising:
using a mobile pinpointing device to establish a precise position of the cable fault based on an approximate position of the cable fault that was established previously,
determining a distance of the fault location of the cable from a present position of the mobile pinpointing device by the mobile pinpointing device,
using a GPS receiver of the mobile pinpointing device to capture the present position of the mobile pinpointing device,
determining at least one possible precise position of the cable fault by the pinpointing device based on the captured present position of the pinpointing device, the established distance of the fault location from the present position of the pinpointing device, and on the a path of the cable stored in the pinpointing device, and
displaying at least one target location for the precise position of the cable fault on a display of the pinpointing device in a map of an area surrounding the approximate position of the cable fault that is stored in the pinpointing device or in an image recorded by a camera of the mobile pinpointing device.

2. The method as claimed in claim 1, further comprising:
injecting surge voltage impulses into the cable for determining the distance of the fault location from the present position of the mobile pinpointing device,
measuring a time difference between an electromagnetic impulse, which was brought about by one of the surge voltage impulses and is detected using an electromagnetic sensor of the pinpointing device, and an acoustic impulse, which is caused by a flashover in the cable fault triggered by said surge voltage impulse and is detected using a ground microphone, by the mobile pinpointing device, and
determining the distance of the fault location from the present position of the mobile pinpointing device by the pinpointing device from said time difference.

3. The method as claimed in claim 1, further comprising
determining the distance of the mobile pinpointing device from the fault location at at least two different ones of the present positions of the pinpointing device, and in each case determining the possible precise positions of the cable fault based on the path of the cable stored in the pinpointing device, and ascertaining which of the thus determined possible precise positions of the cable fault lie within a tolerance range at a same location, and
displaying at least one target location for the precise position of the cable fault within the tolerance range in the map or in the image on the display of the pinpointing device.

4. The method as claimed in claim 3, further comprising,
of the possible precise positions of the cable fault that were established during the last one of the measurements that were performed, displaying the one that lies within the tolerance range in the map or in the image as the target location.

5. The method as claimed in claim 4, further comprising:
of the possible precise positions of the cable fault that were established in at least one of the measurements performed before a last one of the measurements, displaying one or more positions that lie within the tolerance range in the map or in the image as the target location(s).

6. The method as claimed in claim 3, further comprising:
displaying an average value of at least two of the possible precise positions of the cable fault that were established in the performed measurements and lie within the tolerance range in the map or in the image as the target location.

7. The method as claimed in claim 1, further comprising:
wirelessly effecting a data transfer between a capturing unit, having the ground microphone and the electromagnetic sensor, of the mobile pinpointing device and a display unit, having the display, of the mobile pinpointing device.
